(19) United States
(12) Patent Application Publication
(10) Pub. No.: US 2025/0041908 A1
(43) Pub. Date: Feb. 6, 2025

(54) FLUID AERATOR TO REDUCE SPLASHING

(71) Applicant: Applied Materials, Inc., Santa Clara, CA (US)

(72) Inventors: Jason A. RYE, Kalispell, MT (US); Alex DURADO, Kalispell, MT (US)

(21) Appl. No.: 18/781,131

(22) Filed: Jul. 23, 2024

Related U.S. Application Data
(60) Provisional application No. 63/530,839, filed on Aug. 4, 2023.

(51) Int. Cl. B08B 3/04; B01F 23/23; B01F 23/232; B01F 25/452; B08B 13/00

(52) U.S. Cl. CPC B08B 3/04; B01F 23/2319; B01F 23/232; B01F 25/4523; B08B 13/00

(57) ABSTRACT

Embodiments herein provide a semiconductor substrate cleaning chamber. The cleaning chamber includes side walls that partially define a cleaning volume, a pedestal disposed within the side walls, and a cleaning arm disposed above the pedestal. The cleaning arm includes a nozzle assembly disposed on a nozzle end of the cleaning arm. The nozzle assembly includes a housing, and a body disposed within the housing and having a gas port disposed through the body and configured to aerate a fluid passing through the nozzle assembly.

### CROSS-REFERENCE TO RELATED APPLICATIONS

This application claims priority to U.S. Provisional Patent Application Ser. No. 63/530,839 filed on Aug. 4, 2023 which is herein incorporated by reference in its entirety.

### BACKGROUND

### Field

Embodiments of the present invention generally relate to an apparatus and method of cleaning a wafer for semi-conductor manufacturing. In particular, methods and apparatus to minimize residue from cleaning a wafer are provided.

### Description of the Related Art

Substrate processing units may perform cleaning operations prior to being packaged. The removal of contaminants is always a focus in the semiconductor manufacturing industry. Contaminant removal is dependent on where the substrate is within the manufacturing process. Further, the chamber and a substrate or wafer must be free of residue after cleaning. Efforts to maximize the efficiency of cleaning methods to thereby reduce issues are always a consideration. Thus, there is a need in the art for more efficient apparatus and methods of cleaning substrates

### SUMMARY

Embodiments of the disclosure generally relate to substrate processing systems used in electronic device fabrication processes. More specifically, embodiments relate to components and methods to reduce splashing during the cleaning of semiconductor devices.

In one embodiment, a semiconductor substrate cleaning chamber. The cleaning chamber includes side walls that partially define a cleaning volume, a pedestal disposed within the side walls, and a cleaning arm disposed above the pedestal. The cleaning arm includes a nozzle assembly disposed on a nozzle end of the cleaning arm. The nozzle assembly includes a housing, and a body disposed within the housing and having a gas port disposed through the body and configured to aerate a fluid passing through the nozzle assembly.

In another embodiment, a method of cleaning a substrate having structures. The method includes placing a substrate on pedestal and rotating the pedestal, the substrate having structures disposed on a top face, moving a nozzle assembly over the top face of the substrate, flowing a cleaning fluid to the nozzle assembly, aerating the cleaning fluid in the nozzle assembly, and supplying the aerated cleaning fluid to the top face of the substrate. The nozzle assembly includes a housing and a body having a gas port disposed through the body.

In another embodiment, a semiconductor substrate cleaning nozzle assembly is provided. The cleaning nozzle assembly includes a housing, and a body disposed within the housing. The body includes a polymer material and a gas port disposed through the body and configured to aerate a fluid passing through the nozzle assembly.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a schematic illustration of a cleaning chamber according to some embodiments.

FIG. 2 is a schematic, cross-sectional illustration of a cleaning module from the cleaning chamber of FIG. 1 according to some embodiments.

FIGS. 3A and 3B are schematic illustrations of a nozzle disposed within the cleaning module of FIG. 2 according to some embodiments.

FIG. 4 is schematic illustrations of a nozzle disposed within the cleaning module of FIG. 2 according to some embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to methods and apparatus for forming a thin-form-factor semiconductor package. In one embodiment, a substrate is cleaned prior to being packaged. The methods and apparatus disclosed herein further include novel methods and apparatus to minimize overspray and splash of cleaners during cleaning processes. The methods and apparatus disclosed herein provide semiconductor package cleaning processes that further increase the efficiency of semiconductor substrate cleaning. This efficiency is accomplished by aerating the cleaning fluid prior to the cleaning fluid being applied to the surface of a substrate or wafer. The aerated cleaning fluid provides a turbulent flow of cleaning fluid to the surface of a substrate to remove containments, while minimizing splashing caused by the structures located on the substrate. The addition of an aerating nozzle into the cleaning operation further aids in the cleaning of the substrate because the cleaning fluid has not splashed far from a cleaned area of the substrate to an external surface.

Traditional cleaning chambers provide laminar flow of cleaning fluid that splashes chaotically and unpredictability when supplied to the substrate and is exacerbated when the substrate has structures. The structures create geometries on the subrogate surface that increases the likelihood of non-uniform splashing. The excess droplets from the splashed cleaning fluid can travel a substantial distance and carry contaminants to other parts of the chamber, substrate, and other external surfaces. These contaminants can contaminate the substrate currently being cleaned or subsequent substrates that are to be cleaned in the system or chamber. Additionally keeping the cleaning fluid and contaminants within the controlled chamber environment increases safety and through-put of the system. This disclosure overcomes the contamination issue by aerating the cleaning fluid which in turn minimizes the splashing.

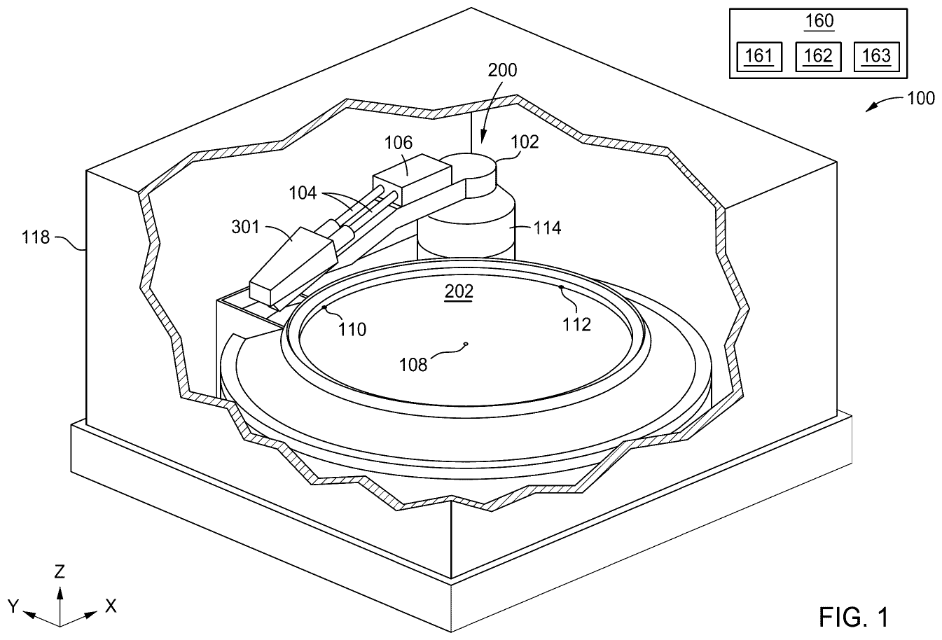

FIG. 1 shows a schematic illustration of a cleaning chamber 100 for advanced packaging according to an embodiment of the present disclosure. The chamber 100 may be a semiconductor substrate cleaning chamber. The cleaning chamber 100 includes a cleaning module 200, chamber walls 118, and a collector 119. The chamber side walls 118 enclose the cleaning module 200 and define a cleaning volume within the cleaning chamber 100. The chamber walls 118 include a port (not shown) to transfer a substrate/wafer 202 in and out of the cleaning chamber 100.

It is desirous to keep cleaning fluid from splashing onto the chamber walls 118 and have all cleaning fluid flow into the collector 119. The collector is disposed within the chamber walls 118 and serves as a means to collect the cleaning fluid as it passes over and falls off the substrate 202.

The cleaning module 200 includes an arm 102 disposed on a rotatable base 114. The base rotates the arm 102 above the substrate 202 while the substrate is rotated by a substrate support assembly (not shown).

The arm 102 includes a supply manifold 106. The supply manifold 106 receives fluids used to clean the substrate 202. The supply manifold 106 may receive fluids through the arm 102. In some embodiments, the supply manifold 106 receives cleaning fluid through fluid inlets (not shown). The fluid leaves the supply manifold 106 through a supply line 104. The arm may have one or more supply lines 104. For example, the arm may include two, three, or four supply lines 104. The supply lines provide cleaning fluid to a nozzle assembly 301.

The nozzle assembly is disposed on the nozzle end on the arm 102. The nozzle end of the arm 102 is radially outward from the rotatable base 114. As shown there are two supply lines 104 that connect the supply manifold 106 to the nozzle assembly 301, but more or less supply lines 104 are contemplated.

The rotatable base 114 is configured to rotate the arm 102 such that the nozzle assembly 301 is able to pass over at least a first edge 110, a center 108, and a second edge 112 of the substrate 202. In some embodiments, the nozzle assembly 301 passes back and forth between at least the first edge 110 and a second edge 112 of the substrate 202. In other embodiments, the nozzle assembly 301 passes back and forth between at least the first edge 110 and a second edge 112 of the substrate 202 while intersection the center 108 of the substrate 202.

While passing over the substrate 202, the nozzle assembly 301 supplies a fluid to the surface of the substrate which is discussed in more detail below.

In some embodiments, operation of the cleaning system 100, is directed by a system controller 160. The system controller 160 includes a programmable central processing unit (CPU) 161 which is operable with a memory 162 (e.g., non-volatile memory) and support circuits 163. The support circuits 163 are conventionally coupled to the CPU 161 and comprise cache, clock circuits, input/output subsystems, power supplies, and the like, and combinations thereof coupled to the various components of the chamber 100, to facilitate control thereof. The CPU 161 is one of any form of general purpose computer processor used in an industrial setting, such as a programmable logic controller (PLC), for controlling various components and sub-processors of the processing system. The memory 162, coupled to the CPU 161, is non-transitory and is typically one or more of readily available memories such as random access memory (RAM), read only memory (ROM), floppy disk drive, hard disk, or any other form of digital storage, local or remote.

Typically, the memory 162 is in the form of a non-transitory computer-readable storage media containing instructions (e.g., non-volatile memory), which when executed by the CPU 161, facilitates the operation of the cleaning system 100. The instructions in the memory 162 are in the form of a program product such as a program that implements the methods of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

Illustrative non-transitory computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory devices, e.g., solid state drives (SSD)) on which information may be permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. In some embodiments, the methods set forth herein, or portions thereof, are performed by one or more application specific integrated circuits (ASICs), field-programmable gate arrays (FPGAs), or other types of hardware implementations. In some other embodiments, the substrate processing and/or handling methods set forth herein are performed by a combination of software routines, ASIC(s), FPGAs and, or, other types of hardware implementations. One or more system controllers 160 may be used with one or any combination of the various modular polishing systems described herein and/or with the individual polishing modules thereof.

The system controller 160 controls, among other things, at least the rotatable base 114 and valves within the supply manifold 106. In some embodiments, each supply line 104, is configured to transport a different fluid to the nozzle assembly 301. In other embodiments, the supply line 104 may transport a gas from a gas supply (not shown), and another supply line 104 may transport a liquid from the tank. In some embodiments, fluid may be pumped through the supply lines 104 to the nozzle assembly 301. In some embodiments, the supply line 104 supplies deionized (DI) water from a DI water source to the nozzle assembly 301. Pumps (not shown) connected to the controller 160 may be used to control the flow of fluid through the supply line 104. In some embodiments, the controller 160 controls valves in the supply manifold 106 (not shown) that measure mass flow rates of fluids and control the mass flow passing through the valves.

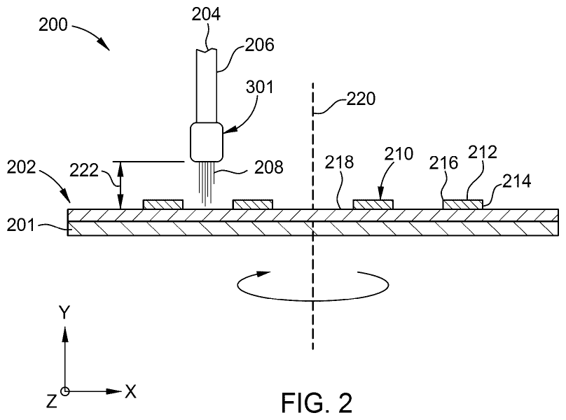

FIG. 2 shows a schematic illustration of the cleaning module 200. The nozzle assembly 301 includes and is connected to a nozzle supply line 204 that supplies cleaning fluid 208 to the nozzle assembly. The nozzle supply line 204 has an exterior surface 206. In some embodiments, the supply line 104 (FIG. 1) is the nozzle supply line 204. In other embodiments, the nozzle supply line 204 is a mixture from supply lines 104 (FIG. 1).

In some embodiments the cleaning fluid 208 is deionized (DI) water. In other embodiments, the cleaning fluid 208 is DI water with other fluids. For example, the cleaning fluid 208 may also include TMAH, NH₄OH, SC1, and other fluids.

The substrate 202 is disposed on a pedestal 201. The pedestal 201 rotates the substrate 202 during operation. The pedestal 201 and substrate 202 rotate about a central axis 220. The pedestal 201 is connected to a motor base (not shown). The motor base rotates the pedestal 201 when the motor base receives instruction from the controller 160. The motor base is connected and communicates with the controller 160. The controller 160 causes the pedestal 201 to rotate at a speed between about 0-3000 rpm. For example, the controller 160 causes the pedestal 201 to rotate between about 100-200 rpm. For example, the controller 160 causes the pedestal 201 to rotate between about 200-300 rpm. For example, the controller 160 causes the pedestal 201 to rotate between about 300-400 rpm. For example, the controller 160 causes the pedestal 201 to rotate between about 400-500 rpm. For example, the controller 160 causes the pedestal 201 to rotate between about 500-600 rpm. For example, the controller 160 causes the pedestal 201 to rotate between about 600-700 rpm. For example, the controller 160 causes the pedestal 201 to rotate between about 700-800 rpm. For example, the controller 160 causes the pedestal 201 to rotate between about 800-900 rpm. For example, the controller 160 causes the pedestal 201 to rotate between about 900-1000 rpm.

Aerated cleaning fluid 208 leaves the nozzle assembly 301 and is supplied to the substrate 202. The substrate has a top face on the substrate surface 218 facing the nozzle assembly 301. The nozzle assembly 301 is disposed a height 222 above the substrate surface 218. The substrate 202 includes one or more structures 210 disposed on the substrate surface 218.

The structures 210 include top surfaces 212, sides 214, and corners 216, where the top 212 and sides 214 meet. The sides 214 of the structures 210, may be the height of the structures. The height of the structures 210 may be between about 100 microns and 1500 micron. In other words, the top surface 212 of the structures 210 may be between about 100 microns and 1500 micron from the surface 218 of the substrate 202.

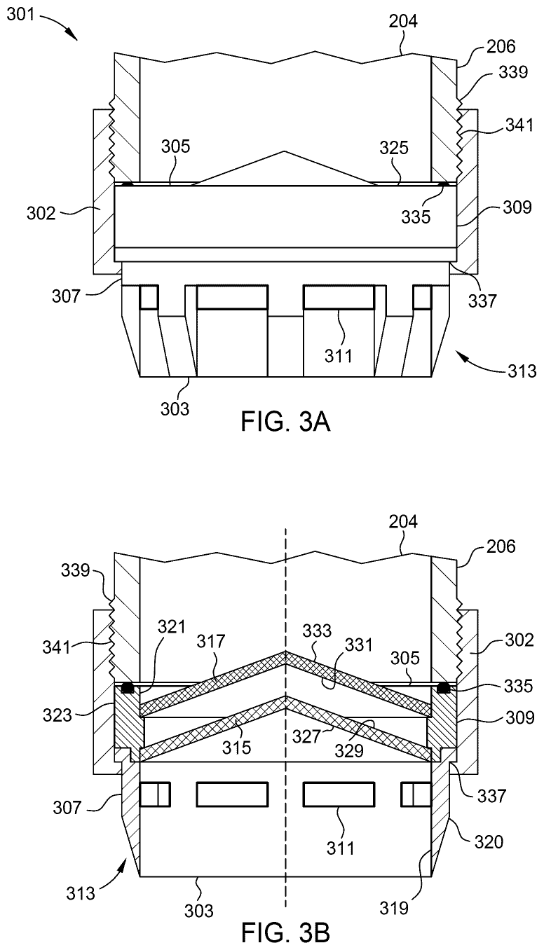

FIGS. 3A and 3B show schematic illustrations of the cleaning nozzle assembly 301 according to some embodiments. FIG. 3A is a partial cross section view of the cleaning nozzle assembly 301. FIG. 3B is a full cross section view of the cleaning nozzle assembly 301. As shown in FIG. 3A, the nozzle assembly 301 has a fluid inlet 305 and a fluid outlet 303. The nozzle supply line 204 is attached to the inlet 305 by a housing 302. The housing 302 surrounds and is disposed radially outward of a retaining ring 309. The housing is also disposed radially outward of the nozzle body 307. The nozzle housing 302 includes securing inlet features 341 disposed proximate to the inlet 305 that secure the nozzle assembly 301 to the nozzle supply line 204. The nozzle supply line 204 has securing outlet features 339 on the exterior surface 206 of the supply line 204. In some embodiments, the securing outlet features 339 and securing inlet features 341 are male and female threads respectively. In other embodiments, the securing outlet features 339 and securing inlet features 341 are female and male threads, respectively.

The retaining ring 309 includes an inlet face 325, an interior face 321, and exterior face 323, and an O-ring 335 disposed in the inlet face 325. In some embodiments, as the nozzle assembly 301 is attached to the nozzle supply line 204, the O-ring 335 is compressed between the inlet face 325 and the nozzle supply line 204 to partially seal the nozzle assembly 301. The nozzle assembly is partially sealed when fluid only leaves the nozzle assembly 301 through the outlet 303. The body 307 is disposed opposite of the inlet face 325 of the retaining ring 309. The body 307 is held by the housing 302 by the connection feature 337. In some embodiments, the connection feature 337 is a housing lip disposed radially inward of the securing inlet features 341 that body 307 rests on. In some embodiments, as the nozzle assembly 301 is attached to the nozzle supply line 204, the body 307 is constrained within the housing 302.

The body includes the outlet 303, gas ports 311, and port cuts 313. During operation, the cleaning fluid 208 (FIG. 2) leaves the nozzle assembly 301 through the outlet 303.

As shown in FIG. 3B, the gas ports 311 are ports that are disposed through the body 307. The gas ports 311 are disposed through the external body face 320, through to the interior body face 319. The port cuts 313 help to channel a gas surrounding the nozzle assembly 301 though the gas ports 311 during operation. According to some embodiments, as cleaning fluid 208 (FIG. 2) passes through the nozzle assembly 301, the cleaning fluid 208 (FIG. 2) pulls gas through the port cuts 313 and gas ports 311, aerating the cleaning fluid 208 before it contacts the substrate 202.

The nozzle assembly 301 also includes one or more internal meshes. As illustrated in FIG. 3B the nozzle assembly 301 includes an inlet mesh 317 and an outlet mesh 315. The nozzle assembly 301 may include additional internal meshes such as three meshes or four meshes according to some embodiments. In other embodiments, the nozzle assembly 301 includes a single internal mesh.

The inlet mesh 317 is disposed and held by the retaining ring 309. The inlet mesh 317 includes an inlet face 333, an outlet face 331, a geometry, and a porosity. The inlet face 333 of the inlet mesh 317 faces the fluid supply line 204. The porosity of the inlet mesh 317 is defined by the density of a lattice within the inlet mesh 317. In other words, the amount volume the lattice occupies between the inlet face 333 and outlet face 331 such that 100% porosity would be a uniform solid body and 0% would mean there is not an inlet mesh 317 present. In some embodiments, the inlet mesh 317 has a porosity between 0% and 100%. For example, the porosity of the inlet mesh 317 is between about 90% and about 70%. For example, the porosity of the inlet mesh 317 is between about 80% and about 60%. For example, the porosity of the inlet mesh 317 is between about 70% and about 50%. For example, the porosity of the inlet mesh 317 is between about 60% and about 40%. For example, the porosity of the inlet mesh 317 is between about 50% and about 30%. For example, the porosity of the inlet mesh 317 is between about 40% and about 20%. The lattice of the inlet mesh 317 may be from cross linked sections. The cross linked sections may have uniform diameters or may have varied diameters.

The inlet mesh 317 includes a geometry. As shown in FIG. 3B, the inlet mesh 317 has a conical geometry, but other geometries are contemplated. For example, the inlet mesh 317 may have a flat disc shape, a trapezoidal shape, an inverse cone shape, a dome shape, or any combination thereof.

The outlet mesh 315 is disposed and held by the retaining ring 309. The outlet mesh 315 includes an inlet face 329, an outlet face 327, a geometry, and a porosity. The inlet face 329 of the outlet mesh 315 faces the fluid supply line 204. The porosity of the outlet mesh 315 is defined by the density of a lattice within the outlet mesh 315. In other words the amount volume the lattice occupies between the inlet face 329 and outlet face 327 such that 100% porosity would be a uniform solid body and 0% would mean there is not an outlet mesh 315 present. In some embodiments, the outlet mesh 315 has a porosity between 0% and 100%. For example, the porosity of the outlet mesh 315 is between about 90% and about 70%. For example, the porosity of the outlet mesh 315 is between about 80% and about 60%. For example, the porosity of the outlet mesh 315 is between about 70% and about 50%. For example, the porosity of the outlet mesh 315 is between about 60% and about 40%. For example, the porosity of the outlet mesh 315 is between about 50% and about 30%. For example, the porosity of the outlet mesh 315 is between about 40% and about 20%. For example, the porosity of the outlet mesh 315 is between about 30% and about 10%. The lattice of the outlet mesh 315 may be from cross linked sections. The cross linked sections may have uniform diameters or may have varied diameters.

The outlet mesh 315 includes a geometry. As shown in FIG. 3B, the outlet mesh 315 has a conical shape, but other geometries are contemplated. For example, the outlet mesh 315 may have a flat disc shape, a trapezoidal shape, an inverse cone shape, a dome shape, or any combination thereof.

In some embodiments the inlet mesh 317 and outlet mesh 315 have the same shape. In other embodiments, the inlet mesh 317 and outlet mesh 315 have substantially about the same shape. In other embodiments, the inlet mesh 317 and outlet mesh 315 have different shapes. For example, the inlet mesh 317 is a flat disc and the outlet mesh 315 is an inverse cone.

In some embodiments the inlet mesh 317 and outlet mesh 315 each have a different porosity. For example, the porosity of the inlet mesh 317 may be greater than the outlet mesh 315. In yet another example, the porosity of the inlet mesh 317 is less than the outlet mesh 315.

The gas ports 311 may be one or multiple gas ports arranged in a circular pattern. The gas ports 311 are disposed between the outlet mesh 315 and the outlet 303. The placement of the gas ports 311 after the outlet mesh 315 helps with aeration because the flow of fluid has been broken up by the internal meshes and can be more aerated than if a mesh or gas port alone was used.

In some embodiments, the nozzle assembly 301 may pull a mixed gas through the gas ports 311. In other words, gas is pulled through the gas port 311 when the cleaning fluid 208 passes through the nozzle assembly. The mixed gas may be ambient air, nitrogen, argon, or any combination thereof.

In some embodiments, the nozzle assembly 301 may be formed of a polymer material, such as polyether ether ketone (PEEK), Polytetrafluoroethylene (PTFE), polyvinylidene fluoride (PVDF) nylon, vinyl, polyurethane, polyethylene, or any combination thereof. Alternatively, the nozzle assembly 301 may be formed of stainless steel, an alloy, a ceramic, or any combination thereof.

In some embodiments, a gas is actively forced into the cleaning fluid 208 to actively aerate the cleaning fluid 208. When actively aerated, gas is injected into the cleaning fluid 208 a specific location. The specific location may be, but is not limited to the supply manifold 106 or the nozzle assembly 301. During active aeration, gas is suppled from a gas source to the chamber 100.

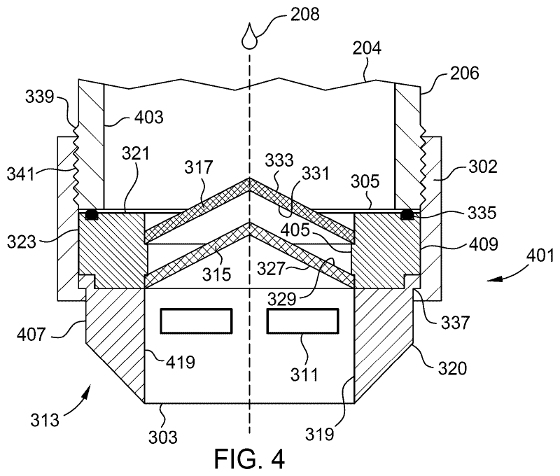

FIG. 4 is a schematic illustration of a nozzle assembly 401 disposed within the cleaning module of FIG. 2 according to some embodiments. FIG. 4 is a full cross section view of the cleaning nozzle assembly 401. The cleaning nozzle assembly 401 is similar to the nozzle assembly 301 (FIGS. 3A & 3B). In operation the cleaning fluid 208 is pumped to the cleaning chamber 100. The cleaning fluid 208 is routed to the supply manifold 106 and then to the nozzle assembly 401. The cleaning fluid 208 may be pumped between about 0.1 L/min to about 8 L/min. For example, the cleaning fluid 208 may be pumped at about 1.0 L/min. In yet another example, the cleaning fluid 208 may be pumped at about 4.0 L/min. In yet another example, the cleaning fluid 208 may be pumped at about 0.25 L/min.

As shown in FIG. 4, the gas ports 311 are ports that are disposed through a reducing body 407. The gas ports 311 are disposed through the external body face 320, through to the interior body face 419. The nozzle supply line 204 has an interior diameter 403. In some embodiments the interior diameter 403 is about 1 inch to about 0.5 inches. In some embodiments the interior diameter 403 is greater than 1 inch.

The nozzle assembly 401 also includes the one or more internal meshes 315, 317. As illustrated in FIG. 4 the nozzle assembly 401 includes a reducing retaining ring 409 and the reducing body 407 within the housing 302. The housing 302 surrounds and is disposed radially outward of a reducing retaining ring 409. The reducing retaining ring 409 includes an inner diameter 405. The inner diameter 405 is less than the interior diameter 403 of the nozzle supply line 204. The diameter of the interior body face 419 is less than the interior diameter 403 of the nozzle supply line 204. Without being bound by theory, the inventors believe that by reducing the diameter through which the cleaning fluid 208 passes, the cleaning fluid 208 is able to be sufficiently aerated at low flow rates and/or reduced velocities. For example, by utilizing the reducing retaining ring 409, in the nozzle assembly 401, when cleaning fluid 208 has a flow rate of less than 0.5 L/min, the cleaning fluid 208 is still aerated and has a turbulent flow. The nozzle assembly 401 enables the cleaning fluid 208 to have a Reynolds number greater than 3500.

In some embodiments the diameter of the interior body face 419 is 0.25 inches less than the interior diameter 403 of the nozzle supply line 204. This reduction further enables the nozzle assembly 401 to be applied to systems where the supply line 204 cannot be switched for supply line 204 with a reduced diameter.

In some embodiments the nozzle assembly 401 experiences a flow rate of cleaning fluid 208 at less than 0.5 L/min at a pressure of about 30 psi to about 20 psi. The one or more internal meshes 315, 317 and the reducing retaining ring 409 are configured so that a pressure delta of less than 10 psi is across the nozzle assembly 401 while the cleaning fluid 208 remains at a turbulent flow with minimal increases in velocity of the cleaning fluid 208.

The rotatable base 114 swings the cleaning arm 102 back and forth across the surface 218 of the substrate 202 distributing the aerated cleaning fluid 208. The distribution of the aerated cleaning fluid 208 removes contaminants from the structures 210 and the surface 218 of the substrate 202. Not to be bound by theory, the inventors, have found the surprising benefit that the additional aeration of the cleaning fluid 208 helps to minimize splashes that occur during distribution when compared to non-aerated cleaning fluid because the passive addition of gas reduces a spring effect without atomizing or aerosolizing the cleaning fluid 208. For example, the nozzle assembly 301 reduces the distance cleaning fluid 208 travels when it splashes by more than 10%. For example, the nozzle assembly 301 reduces the distance cleaning fluid 208 travels when it splashes by more than 30%. For example, the nozzle assembly 301 reduces the distance cleaning fluid 208 travels when it splashes by 50% or more.

The embodiments described herein enable a cleaning operation with enhanced cleaning ability and splash reduction. The splash reduction provides enhanced contaminant resistance. This enhancement is due to the decrease the splashed cleaning fluid travels.

What is claimed is:

1. A semiconductor substrate cleaning chamber, comprising:
side walls that partially define a cleaning volume;
a pedestal disposed within the side walls;
a cleaning arm disposed above the pedestal, the cleaning arm comprising:
a nozzle assembly disposed on a nozzle end of the cleaning arm, the nozzle assembly comprising:
a housing; and
a body disposed within the housing and having a gas port disposed through the body and configured to aerate a fluid passing through the nozzle assembly.

2. The semiconductor substrate cleaning chamber of claim 1, wherein the body comprises a polymer material.

3. The semiconductor substrate cleaning chamber of claim 2, wherein the body further comprises:
a fluid inlet disposed in the housing;
a retaining ring disposed opposite of the fluid inlet, the retaining ring comprising:
an inlet mesh having a first porosity and disposed radially inward of the retaining ring; and
an outlet mesh, having a second porosity, the outlet mesh disposed radially inward of the retaining ring and between the first mesh and the gas port; and
a connection feature disposed on an interior of the housing; and the retaining ring, the inlet mesh, and the outlet mesh comprise the polymer material.

4. The semiconductor substrate cleaning chamber of claim 3, wherein the body, the gas port, the inlet mesh, and the outlet mesh are configured to aerate a cleaning fluid by pulling a gas through the gas port as the cleaning fluid passes from the fluid inlet to a fluid outlet.

5. The semiconductor substrate cleaning chamber of claim 3, wherein the inlet mesh further comprises a conical geometry.

6. The semiconductor substrate cleaning chamber of claim 5, wherein the outlet mesh further comprises a geometry different than the geometry of the inlet mesh.

7. The semiconductor substrate cleaning chamber of claim 3, wherein the first porosity is greater than second porosity.

8. The semiconductor substrate cleaning chamber of claim 3, wherein the inlet mesh, the outlet mesh and the gas port are configured to reduce a distance a cleaning fluid travels from a surface of a substrate by 30% or greater.

9. A method of cleaning a substrate having structures, the method comprising:
placing a substrate on pedestal and rotating the pedestal, the substrate having structures disposed on a top face;
moving a nozzle assembly over the top face of the substrate, the nozzle assembly comprising:
a housing; and
a body having a gas port disposed through the body flowing a cleaning fluid to the nozzle assembly;
aerating the cleaning fluid in the nozzle assembly; and
supplying the aerated cleaning fluid to the top face of the substrate.

10. The method of claim 9, wherein the cleaning fluid is aerated by a gas being pulled through the gas port.

11. The method of claim 9, wherein the cleaning fluid is aerated by a gas being supplied from a gas source.

12. The method of claim 9, wherein the pedestal is rotated at a speed greater than 100 rpm.

13. The method of claim 9, wherein the body comprises a polymer material.

14. The method of claim 13, wherein the nozzle assembly further comprises:
a fluid inlet disposed in the housing; and
a retaining ring disposed opposite of the fluid inlet, the retaining ring comprising:
a connection feature disposed between a fluid outlet and the fluid inlet;
an inlet mesh having a first porosity and disposed radially inward of the retaining ring; and
an outlet mesh, having a second porosity, the outlet mesh disposed radially inward of the retaining ring and between the first mesh and gas port.

15. The method of claim 14, wherein the nozzle assembly further comprises a connection feature disposed on an interior of the housing; and the retaining ring, the inlet mesh, and the outlet mesh comprise the polymer material.

16. The method of claim 14, wherein the body, the gas port, the inlet mesh, and the outlet mesh are configured to aerate a cleaning fluid by pulling a gas through the gas port as the cleaning fluid passes from the fluid inlet to the fluid outlet.

17. The method of claim 14, wherein the outlet mesh further comprises a geometry different than the geometry of the inlet mesh.

18. The method of claim 14, wherein the first porosity is greater than second porosity.

19. The method of claim 14, wherein the inlet mesh, the outlet mesh and the gas port are configured to reduce a distance a cleaning fluid travels from a surface of a substrate by 30% or greater.

20. A semiconductor substrate cleaning nozzle assembly, the cleaning nozzle assembly comprising:
a housing;
a body disposed within the housing, the body comprising:
a polymer material; and
a gas port disposed through the body and configured to aerate a fluid passing through the nozzle assembly.
